(19) United States
(12) Patent Application Publication
(10) Pub. No.: US 2016/0377694 A1
(43) Pub. Date: Dec. 29, 2016

(54) METHOD AND SYSTEM FOR CORRECTING ACQUISITION CHANNEL OF MERGING UINIT IN POWER SYSTEM

(71) Applicants: XJ GROUP CORPORATION, Xuchang (CN); XJ ELECTRIC CO.,LTD, Xuchang (CN); XUCHANG XJ SOFTWARE TECHNOLOGIES LTD, Xuchang (CN); STATE GRID CORPORATION OF CHINA, Beijing (CN)

(72) Inventors: Yanfeng Song, Xuchang (CN); Wen Du, Xuchang (CN); Tuofu Zheng, Xuchang (CN); Yingbing Zhao, Xuchang (CN); Chen Shen, Xuchang (CN); Yunsong Xu, Xuchang (CN); Yang Tang, Xuchang (CN); Fang Yang, Xuchang (CN); Liuyi Ye, Xuchang (CN); Yuan Ji, Xuchang (CN)

(73) Assignees: XJ GROUP CORPORATION; XJ ELECTRIC CO., LTD

(21) Appl. No.: 15/076,411

(22) Filed: Mar. 21, 2016

(30) Foreign Application Priority Data
Jun. 23, 2015 (CN) 201510355684.1

(51) Int. Cl. G01R 35/00; G01R 21/133

(52) U.S. Cl. CPC G01R 35/005; G01R 21/133

(57) ABSTRACT

The present invention relates to a method and system for correcting acquisition channel of merging unit in power system which belong to the technical field of simulation data collection of power system. The present invention performs data acquisition of each channel firstly, and the acquired data is continuous and effective frequency data, then the collected data is stored to their respective backup areas, and the data storage is stopped until the amount of stored data is up to a predetermined value required for correcting, the data is corrected finally within the respective backup areas of each channel which stops the data storage. The correction process is performed by using corresponding correction module. The method for the channel correction improves the efficiency of channel correction greatly, reduces the correction error, improves the correction precision, and has more simple and convenient operation in comparison to the conventional method for channel correction by modifying hardware parameters.

### TECHNICAL FIELD

The present invention relates to a technical field of simulation data collection of power system and more particularly to a method and system for correcting acquisition channel of merging unit in power system.

### BACKGROUND

In the present power system, a process layer performs real-time electric quantity testing of power operation, state parameter testing of operating equipment, operational control execution and driving. The operational control execution is generally referred to the executions of analog quantity, switch signal acquisition. A process layer equipment includes a photoelectric transformer, a merging unit, and a smart terminal. The merging unit is connected with output of the photoelectric transformer to complete data transformation between several merging units in different spaces.

The merging unit is an interface equipment of voltage inductor and current inductor. With the promotion and construction process of automation technology of digital substation, the requirement for functionality and performance of the merging unit becomes increasingly higher, at the same time so does the requirement for the data acquiring and processing ability of the merging units with conventional electro-magnetic transformers interface equipment. The merging units are all the ones with conventional sampling function hereinafter, no more description in detail for them. Because precision of acquiring board of the merging unit is associated with itself and circumstance thereof, it is necessary to correct the parameters of the acquisition channel before the merging unit leaving the factory and being put into operation, and cure parameters of the acquisition channel. The typical conventional steps of the conventional ways for correcting acquisition channel are as follows:

(1) Configuring the corresponding relationship between analog channels of merging unit and 9-2 data output of the merging unit;
(2) Turning on message monitoring tool for monitoring 9-2 message output of the merging unit;
(3) Turning on acquisition board configuration tool of upper machine, adjusting zero drift of channels by software, and observing whether the 9-2 message output waveform of the message monitoring tools started at step 1 overlaps with the 0 group of corresponding channel, if not overlaps, continuing to adjust the zero drift until the waveform overlaps;
(4) Correcting coefficient after completion of correcting the zero drift, adjusting amplitude parameters of configuration tool of the acquisition board and observing whether the nominal 9-2 message output of the message monitoring tool corresponds to the input type and amplitude of the channel, if not, continuing to adjust the amplitude until corresponding,
(5) Correcting phase of the analog channel by the mutual inductor calibration after the adjusting of channel coefficient and zero drift. Detecting the phase difference between the analog channel and a test instrument, by applying rated voltage to transformer calibrator and channels of the merging unit via testing instrument of analogue value, wherein phase difference between the first and the second group of phase voltage channels should be tested; considering phase difference between the first and second group of all phase voltages; adjusting delay of the collector corresponding to a voltage connector. Adjusting the phase parameters of the configuration tool for collector plate, adjusting phase different between all phase voltage channels of the merging unit and tester to be within a required accuracy;
(6) Correcting the next channel, by repeating the above steps, until the correction of the acquisition board for all channels is finished;
(7) At the last, curing the afore-determined zero drift, coefficient and phase of each channel to the acquisition board.

The whole process of correction method above is very complicated, inefficient, there are a dozen of acquisition channels in one merging unit generally, it takes lots of time and energy to correct all the channels, and needs to observe the precision of data output constantly during process of correction, which causes of making a mistake easily. An experienced employee requires at least 20 minutes to correct channel parameter of one device through conventional method, resulting in waste of time and energy.

### SUMMARY

It is an object of the present invention to provide a method for correcting acquisition channel of merging unit in power system. The present invention is able to solve the problems of the complicated and low efficiency process of correcting acquisition.

To solve the above problems, the present invention provides a method for correcting acquisition channel of merging unit in power system, the steps of the correction method are as follows:

1). Getting continuous and effective frequency data of each channel within the merging unit;
2). Storing the acquired data to their respective backup area, as shown in FIG. 3, and then stopping the data storage until the data stored is up to a predetermined value required for correcting;
3). Correcting the data stored in the respective backup areas of each channel stopping the data storage. The correction process is performed by use of corresponding correction modules.

At step 1, the amount of data stored in the backup areas of channel is integer times of cycle sampling points number.

At step 3, the correction module includes a zero drift correction module, a coefficient correction module and a phase correction module, the coefficient correction module is performed by comparing effective amplitude stored in the backup areas with nominal amplitude, the phase correction module is performed by comparing angle value stored in the backup areas with the nominal channel.

Emptying the data stored in backup areas and continuing to store the channel acquired data after correction completed.

The correction process of zero drift correction module are as follows:

A. Calculating the average data value stored in the backup areas of the present channel;
B. Calculating zero offset value of each sampling point by subtracting the average data value of the present channel from the data values of all points in the backup area;
C. Getting the zero offset value of the present channel by calculating the average for the zero offset values of all points calculated.

The correction process of coefficient correction module are as follows:

a. Calculating data values of each sampling point without affection of zero offset-real samples values by subtracting the zero offset value of the channel from the data value of each sampling point in the backup area;
b. Calculating the valid values of fundamental wave of the channel using the real samples values obtained according to the Fourier transform;
c. Calculating the real digital output value of the channel according to the valid values of the fundamental wave, and then calculating the coefficient shift of the present channel by comparing the real digital output with the nominal digital output.

The correction process of phase correction module are as follows:

1). Calculating data values of each sampling point without affection of zero offset-real samples values by subtracting the zero offset value of the channel from the data value of each sampling point in the backup area;
2). Calculating the real parts, imaginary parts of fundamental wave of the channel using the real samples values obtained according to the Fourier transform;
3). Calculating the phase value of the channel according to the real parts, imaginary parts of fundamental wave and then calculating the phase shift of the channel by comparing the phase value of the channel with the phase of the specified reference channel.

The present invention also provides a correction system for correcting acquisition channel of merging unit in power system. The correction system includes channel data acquisition module and channel correction module, according the present invention, and the channel data acquisition module performs data acquisition of each channel, the acquired data is continuous and effective frequency data. The acquired data is stored to their respective backup areas, and the data storage is stopped until the amount of data stored is up to a predetermined value required for correcting; the channel correction module corrects the data within the respective backup areas of each channel which stops the data storage, there are correction configuration files in the channel correction module, the channel correction module corrects collected channel data by using corresponding correction algorithm in correction configuration files.

The Correction algorithm of the correction configuration files includes the zero drift correction, the coefficient correction and of the phase. correction The zero drift correction is performed by using cycle mean algorithm. The coefficient correction is performed by comparing effective amplitude with nominal amplitude stored in the backup areas. The phase correction is performed by comparing angle value stored in the backup areas with the nominal channel.

Emptying the data stored in backup areas and continuing to store the channel acquired data by channel data acquisition module after correction completed.

The invention has advantages of that: the present invention performs data acquisition of each channel first, wherein the acquired data is continuous and effective frequency data, then the acquired data is stored to their respective backup area, and the data storage is stopped until the amount of stored data is up to a predetermined value required for correcting, at the last the data is corrected within the respective backup area of each channel which stops the data storage. The correction process is performed by using corresponding correction module. The method for the channel correction improves the efficiency of channel correction greatly, reduces the correction error, improves the correction precision, and has more simple and convenient operation in comparison to the conventional method for channel correction by modifying hardware parameters.

### BRIEF DESCRIPTION OF THE DRAWINGS

FIG. 1 is a schematic diagram showing channel correction of the merging unit according to the present invention;

FIG. 2 is a process diagram showing channel correction of the merging unit according to the present invention;

FIG. 3 is a schematic diagram showing realization of channel correction of the merging unit according to the present invention;

FIG. 4 is a overall process diagram showing collection data task of channel of the merging unit according to the present invention;

FIG. 5 is a overall process diagram showing the channel correction data task of the merging unit according to the present invention;

FIG. 6 is a process diagram showing zero drift correction;

FIG. 7 is a process diagram showing coefficient correction;

FIG. 8 is a process diagram showing phase correction.

### DETAILED DESCRIPTION

An embodiment of the invention will be described in detail below with reference to the drawings.

The steps of method for correcting acquisition channel of merging unit in power system according to the present invention are as follows:

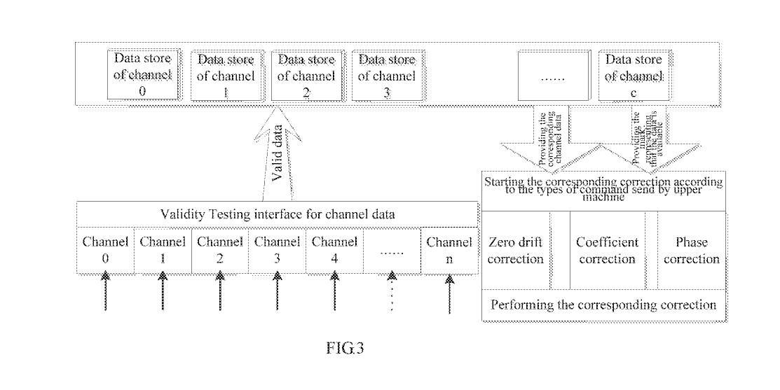

1). Performing acquired data of each channel, the acquired data is continuous and effective frequency data;
2). Storing the acquired data to their respective backup area, as shown in FIG. 3, and then stopping the data storage until the data stored is up to a predetermined value required for correcting.
3). Correcting the data stored in the respective backup areas of each channel stopping the data storage. The correction process is performed by use of corresponding correction modules.

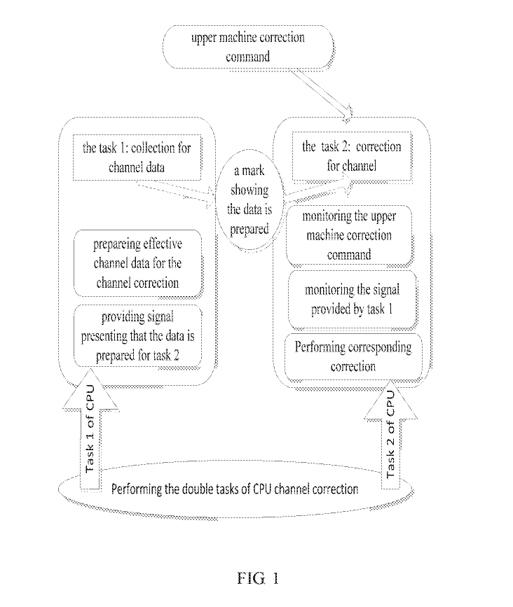

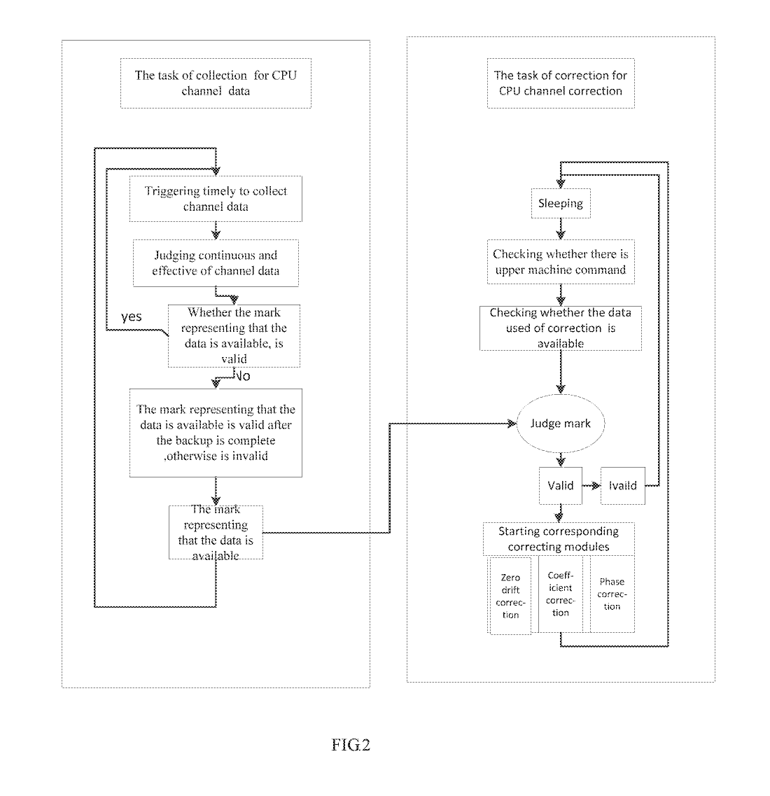

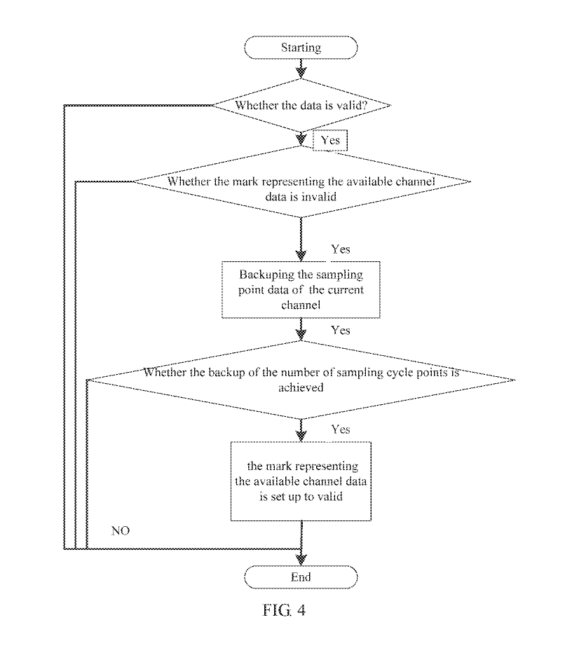

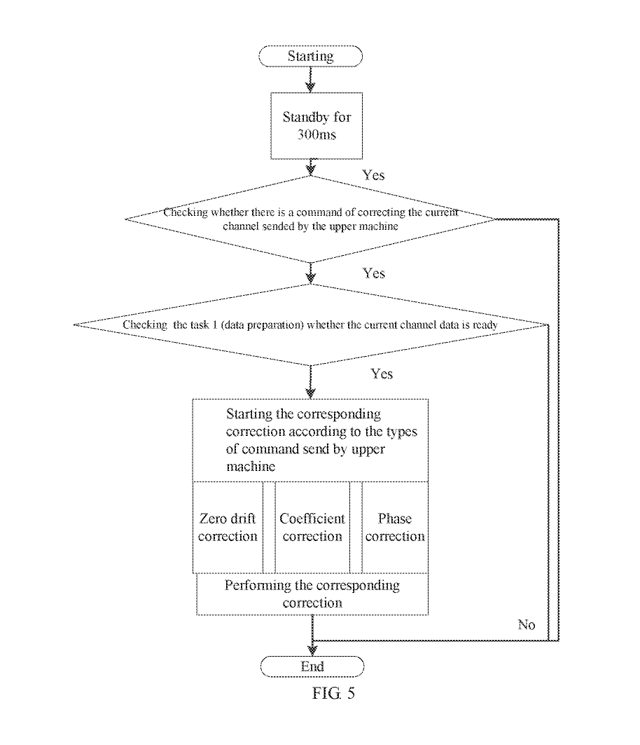

The process is completed within the merging unit by performing two parallel tasks: the two parallel tasks are collection for channel data and channel correction, as shown in FIG. 4 and FIG. 5, the role of the task for the data collection is to prepare effective channel data for the channel correction; the role of the task for channel correction is to perform correction for zero drift, coefficient, phase, according to different algorithms by using the channel data prepared by the task for collection data. The tasks for collection data are to perform data collection for each channel, and make sure that the acquired data is continuous and effective frequency data, and store the acquired data to their respective backup area, and stop the data storage until the data stored is up to a predetermined value required for correcting, and send a sign showing that the channel data becomes ready to the channel correction to be used, as shown in FIG. 1 and FIG. 2.

The task for channel correction begins to perform corresponding channel correction according to correction commands from upper computer software in a case of the channel data in the data collection task is ready. Statisticing channel sampling data for a certain period in the state of that the acquisition channel do not have adding amount, and then calculating the zero offset value of the channel according to a special algorithm; and then calculating the coefficient of the channel according to collected cycle data, channel type and zero offset value and etc, in the state of that the channel acquisition channel has the adding amount; selecting one of the channels as a reference channel, and calculating the phase shift of the other channels relative to the reference channel, according to a special algorithm. These process of correction calculation are performed automatically by the merging unit, which performs corresponding correction only requiring that the upper machine send a corresponding correction signal. The method for the channel correction improves the efficiency of channel correction greatly, reduces the correction error, improves the correction precision, and has more simple and convenient operation in comparison to the conventional method for channel correction by modifying hardware parameters. The correction process of each correction module in detail is as following:

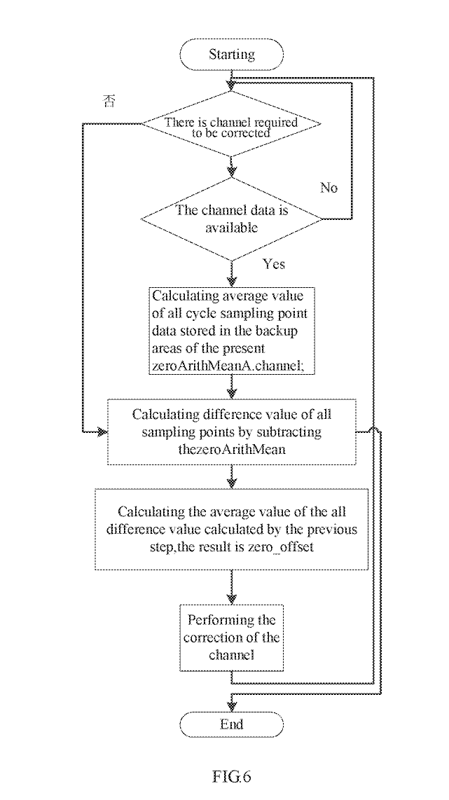

The process of zero drift correction, as shown in FIG. 6

1). Determining whether there is upper machine command of correction for zero drift of the present channel, and whether the data for correction of the present channel is ready;
2). Executing the channel correction algorithm program if determination result is “yes”;
3). Calculating the average data value stored in the backup areas of the present channel, and then calculating zero offset value of each sampling point by subtracting the average data value of the present channel from the data values of all points in the backup area;
4). Getting the zero offset value of the present channel by calculating the average for the zero offset values of all points calculated by the step 3;

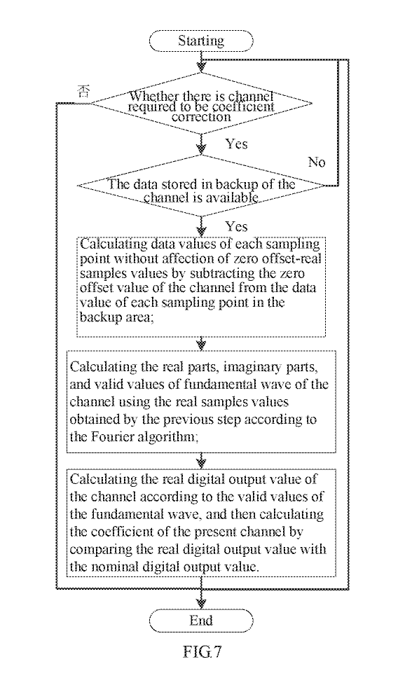

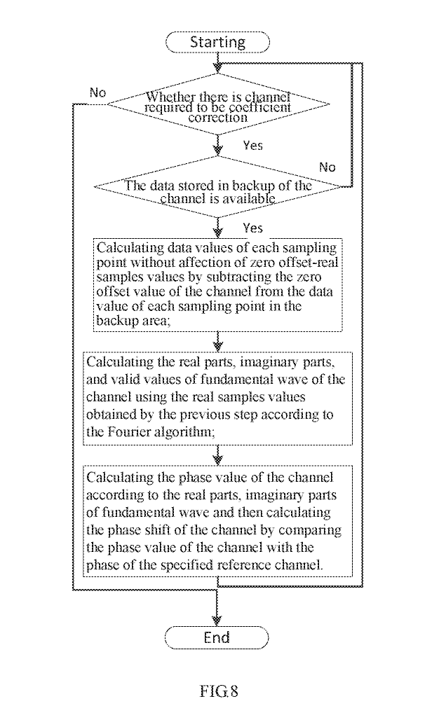

The process of calculating coefficient and phase shift is performed after calculating the zero drift. The FIGS. 7 and 8 show the process for correction of coefficient and phase shift in detail as follows:

a). Determine whether there is upper machine command of correction the coefficient and phase shift, and whether the data for the present channel is ready;
b). Executing the channel correction algorithm program if result of the determination is “yes”;
c). Calculating data values of each sampling point without affection of zero offset-real samples values by subtracting the zero offset value of the channel from the data value of each sampling point in the backup area;
d). Calculating the real parts, imaginary parts, and valid values of fundamental wave of the channel using the real samples values obtained after correction of zero drift according to the Fourier algorithm;
e). Calculating the real digital output value of the channel according to the valid values of the fundamental wave;
f). Calculating the coefficient shift of the present channel by comparing the real digital output with the nominal digital output;
g). Calculating the phase value of the channel according to the real parts, imaginary parts of fundamental wave;
h). Calculating the phase shift of the channel by comparing the phase of the specified reference channel;
i). Curing the parameters having been corrected into a correction configuration file of merging unit channel.

The zero drift, coefficient and phase and the other parameters are read from the channel of the merging unit when the device is restarted, and data correction is performed when each channel acquires data.

Because the Fourier algorithm is used by correction coefficient and correction phase, the below gives a simple description for the Fourier algorithm:

The Fourier transform is an important algorithm in the field of digital signal processing, Any sequential or signal measured continuously can be represented as infinite superposition of sinusoidal waves with various frequencies. The Fourier transform prompted according to the principle uses an original signal obtained by directly measuring to calculate frequency, amplitude and phase of different sinusoidal waves in the signal with various frequencies in a cumulative way. The Fourier transform converts time domain signal that is difficult to deal with into frequency domain signal that is easy to deal with (signal spectrum), and some tools may be used to deal with these frequency domain signal. At last the Fourier transform is also used to convert the frequency domain signal into time domain signal. The Fourier transform is a special integral transform, it represented a function satisfying certain conditions as linear combination of sine basis function or integral of sine basis function.

The Fourier algorithm can be expressed by equations as follows:

$$Hc [ i ] = \frac{2}{N} * cos \frac{2 ( i + 1 ) π}{N} , i = 0 , 1 , … , N - 1$$

$$Hs [ i ] = - \frac{2}{N} * sin \frac{2 ( i + 1 ) π}{N} , i = 0 , 1 , … , N - 1$$

wherein the coefficient “N” is a number of cycle sampling, the Hc[i] and Hc[i] are Fourier coefficients of the ith data point, for example, the Fourier coefficient can be expressed by equations as follows when the number is 80:

$$Hc [ i ] = \frac{1}{40} * cos \frac{( i + 1 ) π}{40} , i = 0 , 1 , … , N - 1$$

$$Hs [ i ] = - \frac{1}{40} * sin \frac{( i + 1 ) π}{40} , i = 0 , 1 , … , N - 1$$

Getting the Fourier coefficient by the Fourier coefficient table calculated according to different cycle sampling number for reducing the burden of the CPU and avoiding to calculate Fourier coefficient repeatedly.

The algorithm of phase coefficient can be expressed by equations as follows:

$$Ure = {\sum }_{i = 0}^{N - 1} U [ i ] * Hc [ i ] ;$$

$$Uim = {\sum }_{i = 0}^{N - 1} U [ i ] * Hs [ i ] ;$$

wherein the U[i] is sampling values of the ith data point, Hc, Hs should be circular addressing. At last, fundamental effective value is calculated, which can be expressed by an equation:

\sqrt{Ure²+Uim²}

The real digital output value can be figured out based on the fundamental effective value. The channel coefficient can be figured out by comparing the real digital output value with the nominal digital output value (coefficient offset value), which is relevant to the channel type. The specific mapping relation is expressed as shown in table 1; the channel phase value can be figured out by calculating the real part and imaginary part of fundamental wave; the phase offset value of the present channel can be figured out by comparing the channel phase value with the phase of the specified reference channel.

TABLE 1

| | | Analog | |
|---|---|---|---|
| Number | Channel Type | Input | Digital Output |
| 1 | Protecting electricity channel | 5A/1A | 463 |
| 2 | Testing electricity channel | 5A/1A | 11585 |
| 3 | Phase voltage channel | 57.74 V | 11585 |
| 4 | Zero sequence voltage channel | 60 V | 2317 |

Above all, the method for channel automatic correction according the present invention is efficient and very high precision. The method gives a great helpful for improving the efficiency of production and test for a conventional merging unit,

The present invention relates to a method and system for correcting acquisition channel of merging unit in power system

An embodiment of a correcting system for acquisition channel of merging unit in power system of the present invention.

The correction system includes channel data acquisition module and channel correction module, according the present invention, and the channel data acquisition module performs data acquisition of each channel, the acquired data is continuous and effective frequency data. The acquired data is stored to their respective backup areas, and the data storage is stopped until the amount of data stored is up to a predetermined value required for correcting; the channel correction module corrects the data within the respective backup areas of each channel which stops the data storage, there are correction configuration files in the channel correction module, the channel correction module corrects collected channel data by using corresponding correction algorithm in correction configuration files.

The correction process of channel correction module is as follows:

1). Calculating zero offset value using arithmetic average value algorithm;
2). Calculating the real parts, imaginary parts, and valid values of fundamental wave of the channel using the real samples values obtained after correction of zero drift according to the Fourier algorithm;
3). Calculating the coefficient shift of the channel by comparing the real digital output with the nominal digital output;
4). Calculating the phase shift of the channel by comparing the phase of the specified reference channel

The Correction algorithm of the correction configuration files includes correction of zero drift, correction of coefficient, and correction of phase. The correction of zero drift is performed by using cycle mean algorithm. The correction of coefficient is performed by comparing effective amplitude with nominal amplitude stored in the backup areas. The correction of phase is performed by comparing angle value stored in the backup areas with the nominal channel. The specific correction process is the same as the method described in the method embodiment, and thus no more description for it hereinafter.

What is claimed is:

1. A method for correcting acquisition channel of merging unit in power system, the method includes the following steps:
1) Acquiring continuous and effective data of each acquisition channel of the merging unit;
2) Storing the acquired data to their respective backup areas, and stopping data storing process until the amount of the stored data is up to a predetermined value required for correcting;
3) Correcting the data stored in the respective backup area of each acquisition channel whose data storing process stopped, which is performed by use of corresponding correction modules.

2. The method for correcting acquisition channel of merging unit in power system of claim 1, at step 2), the amount of data points stored in the backup areas of the channel is an integral multiple of the amount of cycle-sampling points.

3. The method for correcting acquisition channel of merging unit in power system of claim 2, at step 3), the correction modules including a zero drift correction module, a coefficient correction module and a phase correction module, the zero drift correction executing by using cycle mean algorithm, the coefficient correction is performed by comparing effective amplitude stored in the backup areas with nominal amplitude, and the phase correction is performed by comparing angle value stored in the backup areas with a designated reference channel.

4. The method for correcting acquisition channel of merging unit in power system of claim 3, emptying the data stored in the backup areas after correction being completed, and continuing to store the collected data of the channel.

5. The method for correcting acquisition channel of merging unit in power system of claim 4, the correction process of the zero drift correction module is as follows:
A. Calculating the average value of the sampling-point data stored in the backup areas of the present channel;
B. Calculating zero offset value of each sampling point by subtracting the average value from the data values of each sampling point in the backup areas;
C. Calculating the average value for the zero offset values of all points, as the zero offset value of the present channel.

6. The method for correcting acquisition channel of merging unit in power system of claim 4, the correction process of the coefficient correction module is as follows:
a. Calculating real sampling values of each sampling point by subtracting the zero offset value of the channel from the data value of each sampling point in the backup area of the channel;
b. Calculating the valid values of fundamental wave of the channel using the real sampling values obtained according to the Fourier transform;
c. Calculating the real digital output value of the channel according to the valid values of the fundamental wave, and then calculating the coefficient of the present channel by comparing the real digital output value with the nominal digital output value.

7. The method for correcting acquisition channel of merging unit in power system of claim 4, the correction process of the phase correction module is as follows:
1). Calculating real sampling values of each sampling point by subtracting the zero offset value of the channel from the data value of each sampling point in the backup area of the channel;
2). Calculating the real parts, imaginary parts of the fundamental wave of the channel by conversion of the obtained real samples values of all points according to the Fourier transform;
3). Calculating the phase value of the channel according to the real parts, imaginary parts of the fundamental wave, and then calculating the phase shift value of the channel by comparing the phase value of the channel and the phase of the specified reference channel.

8. A correction system for acquisition channel of merging unit in power system, the correction system includes a channel data acquisition module and a channel correction module, and the channel data acquisition module performs data acquisition of each channel, stores the acquired data to a backup area associated to each data, and stops the data storage until the amount of data is up to a predetermined value required for correcting, wherein the acquired data is continuous and effective frequency data; the channel correction module corrects the data within the respective backup areas of each channel which stops the data storage, by using corresponding correction algorithm in a channel correction configuration files.

9. The correction system for acquisition channel of merging unit in power system, of claim 8, the correction algorithm of the correction configuration files includes correction of zero drift, correction of coefficient, and correction of phase, the correction of zero drift is performed by using cycle mean algorithm, the correction of coefficient is performed by comparing effective amplitude with nominal amplitude stored in the backup areas, the correction of phase is performed by comparing angle value stored in the backup areas with a reference channel.

10. The correction system for acquisition channel of merging unit in power system, of claim 9, the channel correction module empties the data stored in the backup areas after correction being completed, so that the channel data acquisition module continues to backup the channel data.
